(19) United States
(12) Patent Application Publication
(10) Pub. No.: US 2026/0211311 A1
(43) Pub. Date: Jul. 23, 2026

(54) PELLICLE FILM ATTACHMENT DEVICE AND PELLICLE FILM ATTACHMENT METHOD

(71) Applicant: LINTEC Corporation, Tokyo (JP)

(72) Inventor: Takuya HAYASAKA, Tokyo (JP)

(21) Appl. No.: 19/422,797

(22) Filed: Dec. 17, 2025

(30) Foreign Application Priority Data
Jan. 23, 2025 (JP) 2025-010008

(51) Int. Cl. G03F 1/64

(52) U.S. Cl. CPC G03F 1/64

(57) ABSTRACT

A pellicle film attachment device, which is configured to attach a pellicle film to an adherend surface of a frame member, includes an attachment unit configured to attach the pellicle film to the adherend surface to which a liquid adheres; and a dryer configured to dry the pellicle film attached to the adherend surface.

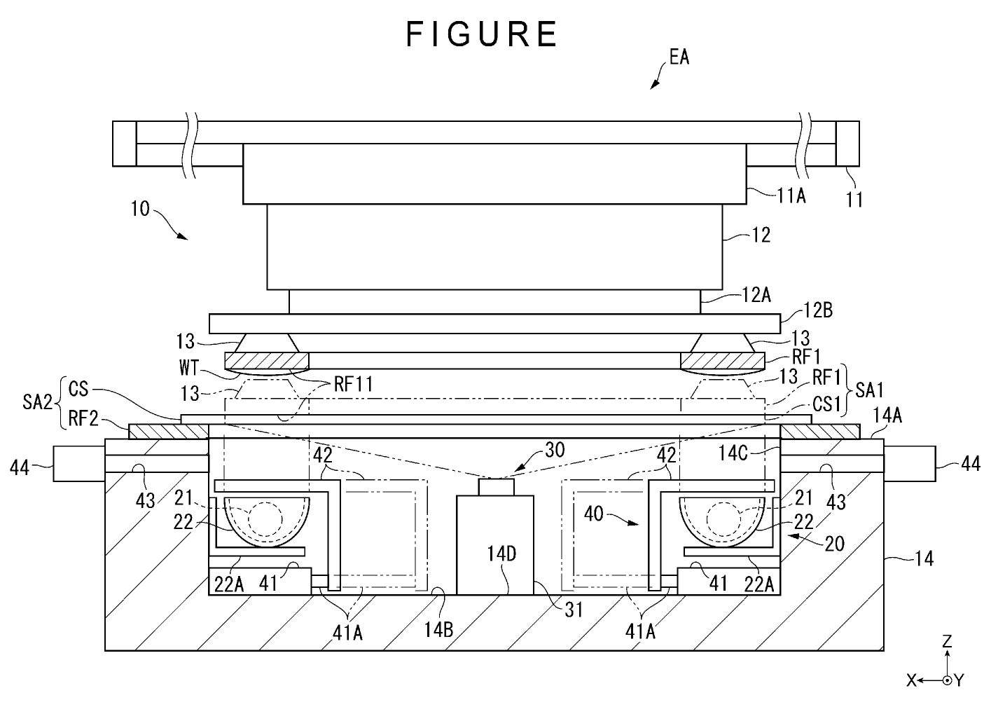

### CROSS REFERENCE TO RELATED APPLICATIONS

The entire disclosure of Japanese Patent Application No. 2025-010008 filed January 23, 2025 is expressly incorporated by reference herein.

### TECHNICAL FIELD

The present invention relates to a pellicle film attachment device and a pellicle film attachment method.

### BACKGROUND ART

A pellicle film attachment device that attaches a pellicle film to an adherend surface of a frame member is known (see, for instance, Literature 1: JP 2020-160345 A).

Literature 1 describes that when a frame-shaped member 190 (frame member) and a carbon nanotube self-supported film 125 (pellicle film) are imposed (attached), water (liquid) is caused to adhere to a portion 190A (adherend surface), which comes into contact with the pellicle film, of the frame member. However, if the pellicle film attached to the adherend surface is transported in a wet state, the pellicle film may peel off from the adherend surface.

### SUMMARY OF THE INVENTION

An object of the invention is to provide a pellicle film attachment device and a pellicle film attachment method that are capable of preventing a pellicle film from peeling off from an adherend surface of a frame member.

An aspect of the invention employs a configuration set forth in the appended claims.

According to the aspect of the invention, since a pellicle film attached to an adherend surface of a frame member is dried, it is possible to prevent the pellicle film from peeling off from the adherend surface.

### BRIEF DESCRIPTION OF DRAWINGS

A figure illustrates a pellicle film attachment device according to an exemplary embodiment of the invention.

### DETAILED DESCRIPTION

An exemplary embodiment of the invention will be described below with reference to the attached figure.

An X-axis, a Y-axis, and a Z-axis in the exemplary embodiment are orthogonal to each other, and the X-axis and the Y-axis are defined as axes in a predetermined plane while the Z-axis is defined as an axis orthogonal to the predetermined plane. Furthermore, in the exemplary embodiment, when viewed from a front side in a direction parallel to the Y-axis of the figure as a reference, an arrow direction of the Z-axis is defined as an "upward" direction and the opposite direction is defined as a "downward" direction; an arrow direction of the X-axis is defined as a "left" direction and the opposite direction is defined as a "right" direction; and the direction parallel to the Y-axis toward the front side of the figure is defined as a "front" direction and the opposite direction is defined as a "rear" direction.

A pellicle film attachment device EA is a device for attaching a pellicle film CS to an adherend surface RF11 of a first frame member RF1 as a frame member, and includes an attachment unit 10, a dryer 20, a cutter unit 30, and a foreign-matter adhesion inhibiting unit 40. The attachment unit 10 performs an attachment step of attaching the pellicle film CS to the adherend surface RF11 to which water WT as a liquid adheres. The dryer 20 performs a drying step of drying the pellicle film CS attached to the adherend surface RF11. The cutter unit 30 performs a cutting step of cutting the pellicle film CS. The foreign-matter adhesion inhibiting unit 40 performs a foreign-matter adhesion inhibiting step of inhibiting foreign matter such as cutting scraps of the pellicle film CS or dust from adhering to the dryer 20.

In the exemplary embodiment, the frame members RF1 and RF2 are each provided in a form of an annular metal member with an opening in the center, and the pellicle film CS is sized to cover the respective openings of the frame members RF1 and RF2. Further, the pellicle film CS is in a form of a sheet including carbon nanotubes. The pellicle film CS and the second frame member RF2 attached to a lower surface of the pellicle film CS form an attachment body SA2.

The attachment unit 10 includes: a linear motor 11 serving as drive equipment; a linear motion motor 12 serving as drive equipment supported by a slider 11A of the linear motor 11; a suction pad(s) 13 serving as a retaining member supported by an output shaft 12A via a bracket 12B of the linear motion motor 12, and capable of retention by suction using a non-illustrated decompression unit such as a decompression pump or a vacuum ejector; and a table 14 serving as a support unit that includes a support surface 14A capable of retention by suction using a non-illustrated decompression unit (retainer) such as a decompression pump or a vacuum ejector, and a recess 14B formed in the support surface 14A.

The dryer 20 includes a plurality of heating units 21 such as halogen heaters and coil heaters for heating the pellicle film CS, and a plurality of heat collection units 22 such as reflectors and lenses for collecting and directing heat generated from the heating units 21 to the pellicle film CS.

Each heat collecting unit 22 is provided for a corresponding heating unit 21, and is supported by a side surface 14C of the recess 14B via a bracket 22A.

The cutter unit 30 includes a laser cutter 31 supported by a bottom surface 14D of the recess 14B.

The foreign-matter adhesion inhibiting unit 40 includes: a plurality of linear motion motors 41 serving as drive equipment supported by the bottom surface 14D of the recess 14B; a cover member 42 that is supported by respective output shafts 41A of the linear motion motors 41 and covers the dryer 20; a plurality of suction holes 43 passing through the table 14; and a plurality of suction units 44 such as vacuum pumps or vacuum ejectors that communicate with the inside of the recess 14B via the suction holes 43.

Operations of the foregoing pellicle film attachment device EA will be described below.

First, a user of the pellicle film attachment device EA (hereinafter, simply referred to as a "user") inputs, through a non-illustrated operation unit such as an operation panel or a personal computer, a signal for starting automatic operation to the pellicle film attachment device EA, the components of which are disposed at respective initial positions illustrated by solid lines in the figure. Subsequently, the user or a non-illustrated transport unit such as an articulated robot or a belt conveyor places the attachment body SA2 on the support surface 14A. The attachment unit 10 then drives a non-illustrated decompression unit to start retaining the attachment body SA2 by suction on the support surface 14A. Thereafter, the user or the non-illustrated transport unit causes the first frame member RF1 with the water WT adhering to the adherend surface RF11 to come into contact with the suction pad 13. The attachment unit 10 then drives a non-illustrated decompression unit to start retaining the first frame member RF1 by suction with the suction pad 13. Subsequently, when the attachment unit 10 drives the linear motion motor 12 to move the first frame member RF1 downward and cause the pellicle film CS to come into contact with the water WT adhering to the adherend surface RF11 as illustrated by two-dot chain lines in the figure, the pellicle film CS is attached to the adherend surface RF11 by capillary force of the water WT.

Then, the foreign-matter adhesion inhibiting unit 40 drives the linear motion motors 41 to move the cover member 42 from above the dryer 20 toward the center of the table 14, as illustrated by two-dot chain lines in the figure. Subsequently, the dryer 20 drives the heating units 21 to heat and dry the pellicle film CS attached to the adherend surface RF11, causing the pellicle film CS to be attached tightly to the adherend surface RF11. Thereafter, the dryer 20 stops the driving of the heating units 21, and then the foreign-matter adhesion inhibiting unit 40 drives the linear motion motors 41 to return the cover member 42 to the initial position. Accordingly, it is possible to inhibit foreign matter from adhering to the dryer 20. Next, the cutter unit 30 drives the laser cutter 31 to cut the pellicle film CS along an outer periphery of the first frame member RF1, forming an attachment body SA1 in which a pellicle film CS1 having a predetermined shape is attached to the first frame member RF1. At this time, the foreign-matter adhesion inhibiting unit 40 drives the suction units 44 to suction foreign matter such as cutting scraps of the pellicle film CS. Then, the attachment unit 10 drives the linear motor 11 and the liner motion motor 12 to transport the attachment body SA1 to the next step, and the user or the non-illustrated transport unit transports the second frame member RF2, to which an unnecessary sheet of the pellicle film CS is attached, to a collection unit such as a box or a cassette. Thereafter, operations similar to those described above are repeated.

According to the exemplary embodiment as described above, since the pellicle film CS attached to the adherend surface RF11 is dried, it is possible to prevent the pellicle film CS from peeling off from the adherend surface RF11 of the first frame member RF1.

The best configuration, method, and the like for carrying out the invention are disclosed in the above description. The invention, however, is not limited thereto. Thus, although the invention is particularly illustrated and described primarily with respect to a specific exemplary embodiment, those skilled in the art may make various modifications to the above exemplary embodiment in terms of shape, material, numerical quantity, and other detailed configurations without departing from the technical idea and the scope of the object of the invention. Further, the descriptions limiting the shapes, materials, and the like disclosed hereinabove are given as examples to facilitate understanding of the invention, and are not intended to limit the invention. Therefore, descriptions in which components are named without some or all of the limitations on shape, material, and the like are within the scope of the invention.

Moreover, the units and steps in the invention are by no means limited as long as the operation, functions, or steps described in connection with the units and steps are achievable, and are in no way limited to the merely exemplary components or steps described in the above exemplary embodiment. For instance, the attachment unit may be any unit capable of attaching a pellicle film to an adherend surface to which a liquid adheres, and is by no means limited insofar as being, in light of common technical knowledge in the art at the time of filing the present application, within a technical scope of the knowledge (the same applies to any other units and steps).

The attachment unit 10 may move the table 14 without moving the first frame member RF1 or while moving the first frame member RF1, and may attach the pellicle film CS to the adherend surface RF11 to which the water WT adheres.

The dryer 20 may dry the pellicle film CS by spraying a heated gas such as air, gas, or the like heated by the heating units 21. Each heating unit 21 may have a shape along the shape of the first frame member RF1. The heating unit 21 and the heat collection unit 22 may be integrated. The pellicle film CS may be dried after being cut. A plurality of heat collection units may be provided for a single heating unit 21. A single heat collection unit may be provided for a plurality of heating units 21. The heat collection units 22 may or may not be provided.

The cutter unit 30 may be disposed to be capable of cutting the pellicle film CS from above. A plurality of cutter units 30 may be provided. The cutter unit 30 may or may not be provided for the pellicle film attachment device EA of the invention. In the case where no cutter unit is provided, the pellicle film CS may be cut with another device.

The foreign-matter adhesion inhibiting unit 40 may support the cover member 42 with output shafts of rotary motors as drive equipment instead of the liner motion motors 41 and may move the cover member 42 from above the dryer 20 by rotating the cover member 42. The foreign-matter adhesion inhibiting unit 40 may support the heat collection units 22 with the output shaft of drive equipment and may dispose the heat collection units 22 above the heating units 21 after the heating step so as to use the heat collection units 22 as a cover member. Before placing the attachment body SA2 on the support surface 14A, the foreign-matter adhesion inhibiting unit 40 may move the cover member 42 from above the dryer 20 toward the center of the table 14. The foreign-matter adhesion inhibiting unit 40 may inhibit adhesion of dust as foreign matter generated by transportation of the attachment body SA2. The foreign-matter adhesion inhibiting unit 40 may or may not be provided for the pellicle film attachment device EA of the invention.

Regarding the liquid to be caused to adhere to the adherend surface RF11, any liquid is usable insofar as the liquid enables the pellicle film CS to be attached to the adherend surface RF11, taking into consideration the characteristics, qualities, properties, materials, compositions, configurations, and the like of the first frame member RF1 and the adherend surface RF11, as well as those of the pellicle film CS. For instance, the liquid may be a polar solvent such as a low-molecular alcohol (e.g., isopropyl alcohol, methanol, and ethanol), a mixed solvent of the water WT and an organic solvent, or a molten metal such as solder, lead, tin, iron, and copper, in addition to an adhesive, resin, varnish, paint, and the like. In particular, in terms of letting no material other than the pellicle film CS remain on the adherend surface RF11, the liquid preferably consists of a component evaporable or volatilizable by heat or air drying, and the liquid is preferably the water WT, an organic solvent, or a mixed solvent thereof.

The pellicle film CS may not be attached to the second frame member RF2 and may be retained by suction with the support surface 14A.

The frame members RF1 and RF2 may be formed, for instance, from metal such as stainless steel, aluminum, copper, or brass, resin such as silicone, fluorine resin, or acrylic resin, or a ceramic material. Silicon or quartz with a low thermal expansion coefficient is preferred. Silicon that is easy to be machined into a desired shape is more preferably used. The shape may be a non-annular shape (a shape having a discontinuous circumference), a circle, an oval, a polygon, or any other shape.

The material, type, shape, and the like of the pellicle film CS and the frame members RF1, RF2 in the invention are not particularly limited. For instance, the frame members RF1, RF2 and the pellicle film CS may be in a shape of a circle, an oval, or a polygon such as a triangle or a quadrangle or in any other shape.

Regarding the drive equipment of the above exemplary embodiment, motorized equipment such as a rotary motor, a linear motion motor, a linear motor, a single-axis robot, or a so-called articulated robot having biaxial or tri- or more axial joints, an actuator such as an air cylinder, a hydraulic cylinder, a rodless cylinder, or a rotary cylinder, and the like, may be used alone, or provided by a direct or indirect combination thereof. Or, one capable or incapable of performing a torque control, a speed control, or the like on an output section of the motorized equipment, the actuator, or the like may be used.

In the above exemplary embodiment, an object (hereinafter, referred to as "object A") and another object (hereinafter, referred to as "object B") movable with respect to the object A, that is, relatively movable object A and object B may be defined as follows. The object B may be moved with respect to the immovable object A, the object A may be moved with respect to the immovable object B, or both the object A and the object B may be moved. It does not matter which one of the object A and the object B is to be moved insofar as the movement achieves the same result. In a case where there is provided an element, such as a support (retaining) unit or a support (retaining) member, that supports (retains) a member to be supported (a member to be retained), the member to be supported may be supported (retained) by a holder such as a mechanical chuck or a chuck cylinder, Coulomb force, an adhesive (an adhesive sheet or an adhesive tape), a sticky agent (a sticky sheet or a sticky tape), magnetic force, Bernoulli suction, suction adsorption, drive equipment, or the like. In a case where there is provided an element, such as a cutter unit or a cutting member, that cuts a member to be cut or makes a cut or a cut line in the member to be cut, the cutting may be performed with, in place of or in combination with the above exemplary element, a cutter blade, a laser cutter, ion beam, firepower, heat, hydraulic pressure, heating wire, or an element that performs cutting by spraying or the like of a gas, a liquid, or the like. Or, the cutting may be performed by moving the object to be cut by a combination of appropriate drive equipment.

What is claimed is:

1. A pellicle film attachment device configured to attach a pellicle film to an adherend surface of a frame member, the device comprising:
an attachment unit configured to attach the pellicle film to the adherend surface to which a liquid adheres; and
a dryer configured to dry the pellicle film attached to the adherend surface.

2. The pellicle film attachment device according to claim 1, wherein the dryer comprises a heat collection unit configured to collect and direct heat generated by a heating unit to the pellicle film.

3. The pellicle film attachment device according to claim 1, further comprising:
a foreign-matter adhesion inhibiting unit configured to inhibit foreign matter from adhering to the dryer.

4. A pellicle film attachment method of attaching a pellicle film to an adherend surface of a frame member, the method comprising:
attaching the pellicle film to the adherend surface to which a liquid adheres; and
drying the pellicle film attached to the adherend surface.
